(19) United States
(12) Patent Application Publication
(10) Pub. No.: US 2026/0020351 A1
(43) Pub. Date: Jan. 15, 2026

(54) MULTI-FINGER ESD PROTECTION DEVICE WITH SYNCHRONOUS TRIGGERING

(71) Applicant: Infineon Technologies AG, Neubiberg (DE)

(72) Inventors: Joost Adriaan Willemen, München (DE); Egle Tylaite, München (DE); Vadim Valentinovic Vendt, Ottobrunn (DE)

(21) Appl. No.: 19/266,340

(22) Filed: Jul. 11, 2025

Related U.S. Application Data
(60) Provisional application No. 63/670,360, filed on Jul. 12, 2024.

(51) Int. Cl. H10D 89/60

(52) U.S. Cl. CPC H10D 89/713

(57) ABSTRACT

A semiconductor device includes a first row of doped wells formed in a semiconductor body, the first row including first conductivity type wells arranged alternatingly with second conductivity type wells in a first direction of the semiconductor body, first and second contact pads disposed over the upper surface of the semiconductor body, a primary electrical interconnect network that electrically couples semiconductor device structures formed by groups of the first conductivity type wells and the second conductivity type wells from the first row between the first and second contact pads, and a secondary electrical interconnect network that forms a node that is independent from the primary electrical interconnect network and electrically connects each of the first conductivity type wells in the first row together.

### TECHNICAL FIELD

The instant application relates to semiconductor devices, and more particularly to electrostatic discharge protection devices.

### BACKGROUND

Components such as transistors, diodes, resistors, electro-optical devices, precision film resistors and a variety of integrated circuits are all sensitive to electrostatic discharge (ESD). As electronics manufacturers drive to miniaturize devices and improve operating speeds, susceptibility of devices to ESD is increasing. For avoiding damage to integrated circuits or electronic devices by pulses during assembly or operation, ESD protection devices are connected between pins of an integrated circuit or between traces on a printed circuit board to prevent a malfunction or breakdown of circuits connected between the pins or traces by ESD current pulses. ESD protection devices are configured to be non-conductive at normal operational levels and become conductive in the presence of an overvoltage from an ESD event to divert damaging current from sensitive elements.

In lateral ESD devices the current capability and clamping performance depend on the width of the device structure, where the width is defined as the dimension perpendicular to the current flow in the semiconductor device structure. A high current capability requires a large total width, usually in the range of hundreds to thousands of micrometers. Usually a wide, lateral device is divided into multiple fingers of the same elementary device design to obtain a compact design. The individual fingers are connected in parallel between two terminals. Each finger may include elongated doped regions such as highly doped shallow regions and doped wells configurated to operate as a, for example, thyristor, silicon controlled rectifier, or bipolar junction transistor. A multi-finger, snap-back device may include trigger devices that are configured to induce conduction by switching the device from a non-conducting into a self-containing, conducting state (in a latching state). It is desirable to create multi-finger devices with synchronous triggering behavior such that each device finger is triggered simultaneously, or, if not triggering simultaneously, to distribute the current-conducting conditions from an already conducting finger to the one or more other fingers that may not have triggered simultaneously. For example, by transferring the potential distribution of doped regions from triggered fingers to not triggered fingers, to bring the not triggered fingers into a conducting state after the original trigger condition of the trigger devices has ceased.

### SUMMARY

Those skilled in the art will recognize additional features and advantages upon reading the following detailed description, and upon viewing the accompanying drawings.

According to an embodiment, a semiconductor device comprises a first row of doped wells formed in an upper surface of a semiconductor body, the first row comprising first conductivity type wells arranged alternatingly with second conductivity type wells in a first direction of the semiconductor body, first and second contact pads disposed over the upper surface of the semiconductor body, a primary electrical interconnect network that electrically couples the first conductivity type wells and the second conductivity type wells from the first row between the first and second contact pads, and a secondary electrical interconnect network that forms a node that is independent from the primary electrical interconnect network and electrically connects each of the first conductivity type wells in the first row together.

According to an embodiment, a semiconductor device comprises a device comprising a plurality of silicon-controlled rectifier devices connected in parallel and electrically coupled to an anode terminal and a cathode terminal via a primary electrical interconnect network, each of the silicon-controlled rectifier devices comprising a trigger device that is configured to create a trigger current that places the device into conduction mode, and a secondary electrical interconnect network that forms a node that is independent from the primary electrical interconnect network and electrically connects a doped region that is part of or coupled with terminals from each of the trigger devices together.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a plan-view layout of an ESD protection device, according to an embodiment.

FIG. 2, which includes FIGS. 2A and 2B, illustrates cross-sectional views of the ESD protection device of FIG. 1, according to an embodiment. FIG. 2A illustrates a cross-sectional view of the ESD protection device along a plane that is outside a trigger region and FIG. 2B illustrates a cross-sectional view of the ESD protection device along a plane that intersects a trigger region.

FIG. 3, which includes FIGS. 3A and 3B, illustrates a plan-view layout of an ESD protection device, according to an embodiment. FIG. 3A illustrates an overall plan-view layout of the device and FIG. 3B illustrates close-up plan-view layout of the device in the vicinity of a single finger including the secondary interconnect network and the trigger regions.

FIG. 4, which includes FIGS. 4A and 4B, illustrates cross-sectional views of the ESD protection device of FIG. 3, according to an embodiment. FIG. 4A illustrates a cross-sectional view of the ESD protection device along a plane that is outside a trigger region and FIG. 4B illustrates a cross-sectional view of the ESD protection device along a plane that intersects a trigger region.

FIG. 5, which includes FIGS. 5A and 5B, schematically illustrates an ESD protection device, according to embodiments. FIG. 5A illustrates the device without a secondary electrical interconnect network and FIG. 5B illustrates the device with a secondary electrical interconnect network.

FIG. 6 illustrates a plan-view layout of an ESD protection device, according to an embodiment.

FIG. 7, which includes FIGS. 7A, 7B, and 7C illustrates plan-view layouts of an ESD protection device, according to embodiments.

FIG. 8, which includes FIGS. 8A, 8B, 8C, 8D, 8E and 8F, schematically illustrates an ESD protection device, according to embodiments.

### DETAILED DESCRIPTION

Embodiments of an ESD protection device are disclosed herein. The ESD protection device is a multi-finger ESD protection device comprising a row of p-type wells and n-type wells arranged alternatingly with one another. The p-type wells and the n-type wells form ESD protection device segments and a primary electrical interconnect network electrically couples these device segments in parallel to two contact pads. The ESD protection device comprises trigger regions that are designed to place the ESD protection device in conduction mode by inducing a current between the p-type wells and n-type wells.

Advantageously, the ESD protection device comprises a secondary electrical interconnect network that electrically couples each like-doped well from the row (i.e., each of the p-type wells or each of the n-type wells) together. This secondary electrical interconnect network forms a separate node from the primary electrical interconnect network that serves only to maintain potential equilibrium between the connected wells. This synchronizes the triggering behavior of the device by mitigating local variations in well-potential, which are related to a state where one or more fingers are triggered, while one or more of the remaining fingers are not triggered.

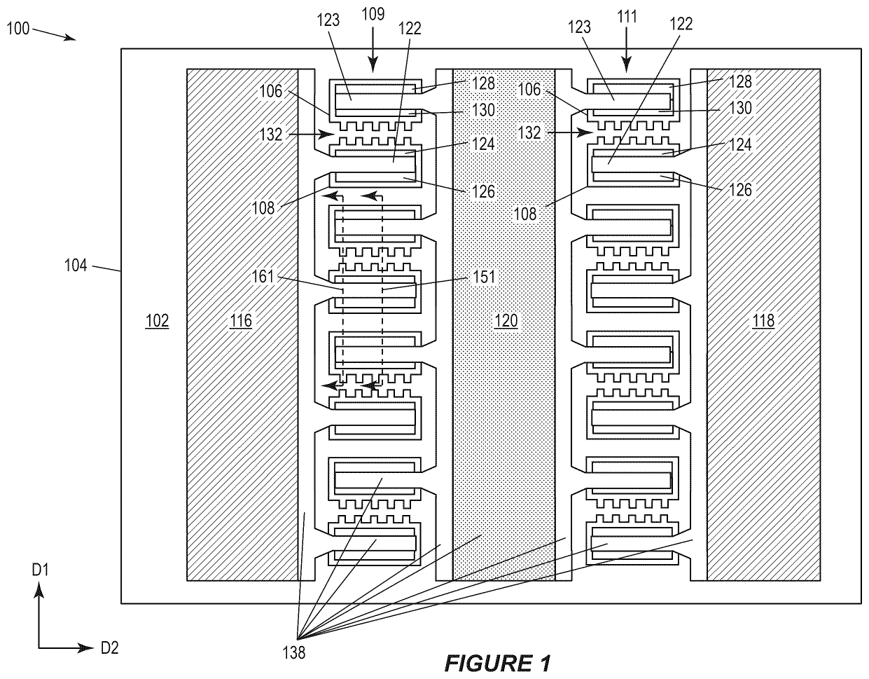

Referring to FIG. 1, an ESD protection device 100 is depicted, according to an embodiment. The ESD protection device 100 is formed in an upper surface 102 of a semiconductor body 104. The semiconductor body 104 may include or consist of a semiconductor material from group IV elemental semiconductors, IV-IV compound semiconductor material, III-V compound semiconductor material, or II-VI compound semiconductor material. Examples of semiconductor materials from the group IV elemental semiconductors include, inter alia, silicon (Si) and germanium (Ge). Examples of IV-IV compound semiconductor materials include, inter alia, silicon carbide (SiC) and silicon germanium (SiGe). Examples of III-V compound semiconductor material include, inter alia, gallium arsenide (GaAs), gallium nitride (GaN), gallium phosphide (GaP), indium phosphide (InP), indium gallium nitride (InGaN) and indium gallium arsenide (InGaAs). Examples of II-VI compound semiconductor materials include, inter alia, cadmium telluride (CdTe), mercury-cadmium-telluride (CdHgTe), and cadmium magnesium telluride (CdMgTe). The semiconductor body 104 may include other active devices, e.g., transistors and in particular power switching devices, e.g., MOSFETs, IGBTs, HEMTs, etc., in addition to the ESD protection device 100. Alternatively, the ESD protection device 100 may be implemented as a discrete device that is configured to protect an external element though external connections, e.g., bond wire connections, PCB connections, etc.

The ESD protection device 100 comprises a plurality of p-type wells 106 and n-type wells 108 formed in the upper surface 102 of the semiconductor body 104. The p-type wells 106 and n-type wells 108 are arranged in rows, wherein the p-type wells 106 and the n-type wells 108 alternate with one another. As shown, the ESD protection device 100 comprises a first row 109 of the p-type wells 106 and n-type wells 108 on the left side of the figure and a second row 111 of the p-type wells 106 and n-type wells 108 on the right side of the figure. In these rows, the p-type wells 106 and the n-type wells 108 alternate with one another along a first direction D1. According to an embodiment, the ESD protection device 100 is configured such that a unit cell comprising, e.g., one of the p-type wells 106 and half of two of the n-type wells 108 on either side of the p-type well 106 (or vice-versa) has a fixed width, thus allowing for the provision of multiple unit cells being arranged next to one another in a regular spacing. For example, each of these unit cells may have a regular width of between 1.0 μm and 15.0 μm.

The ESD protection device 100 comprises first and second shallow doped zones 124, 126 disposed within each of the n-type wells 108. The first and second shallow doped zones 124, 126 have an opposite conductivity type from one another. The first shallow doped zones 124 are p-type regions that form a p-n junction with the subjacent n-type wells 108 and the second shallow doped zones 126 are n-type regions that are more highly doped than the underlying n-type wells 108. Correspondingly, the ESD protection device 100 comprises third and fourth shallow doped zones 128, 130 disposed within each of the p-type wells 106. The third and fourth shallow doped zones 128, 130 have an opposite conductivity type from one another. The third shallow doped zones 128 are p-type regions that are more highly doped than the underlying p-type wells 106. The fourth shallow doped zones 130 are n-type regions that form a p-n junction with the subjacent p-type wells 106.

According to an embodiment, the semiconductor body 104 has a background dopant concentration of no greater than 10¹⁵ dopant atoms/cm³ and more typically in the range of 10¹² dopant atoms/cm³ to 10¹⁴ dopant atoms/cm³. The background dopant concentration of the semiconductor body 104 can be a net p-type or a net n-type concentration and may be selected to be opposite in conductivity type as the wells that are connected to the first and second contact pads 116, 118. The p-type wells 106 and the n-type wells 108 have a higher net dopant concentration than the background dopant concentration of the semiconductor body 104. For example, the n-type wells 108 may have a net n-type dopant concentration of at least 10¹⁵ dopant atoms/cm³ and more typically in the range of 10¹⁷ dopant atoms/cm³. Likewise, the p-type wells 106 may have a net p-type dopant concentration of at least 10¹⁵ dopant atoms/cm³ and more typically in the range of 10¹⁷ dopant atoms/cm³. The first second, third and fourth shallow doped zones 124, 126, 128, 130 have a higher net dopant concentration than the underlying dopant concentration of the n-type wells 108 or the p-type wells 106 that they are formed within. For example, the first and third shallow doped zones 124, 128 may have a net p-type dopant concentration of at least 10¹⁹ dopant atoms/cm³ and more typically in the range of 10¹⁹ dopant atoms/cm³ to 10²¹ dopant atoms/cm³ and the second and fourth shallow doped zones 126, 130 may have a net n-type dopant concentration of at least 10¹⁹ dopant atoms/cm³ and more typically in the range of 10¹⁹ dopant atoms/cm³ to 10²¹ dopant atoms/cm³.

The above-described doped regions of the ESD protection device 100 may be formed using masked implantation techniques. According to an embodiment, the p-type wells 106 are formed by a first implantation process that implants p-type dopants in the semiconductor body 104 and the n-type wells 108 are formed by a second implantation process that implants n-type dopants into the semiconductor body 104. For example, in the case of a semiconductor body 104 formed of silicon, the first implantation process may comprise implanting any one or more of: B, BF, BF₂, Al, etc. into the semiconductor body 104, and the second implantation process may comprise implanting any one or more of: P, As, Bi, etc. into the semiconductor body 104. In this context, the terms “first” and “second” implantation processes do not denote a particular order. The first, second, third and fourth shallow doped zones 124, 126, 128, 130 may be formed by further implantation processes that are performed before or after the first and second implantation processes as described above. For example, the first and third shallow doped zones 124, 128 may be formed by a third implantation process that implants p-type dopants into the semiconductor body 104 and the second and fourth shallow doped zones 126, 130 may be formed by a fourth implantation process that implants n-type dopants into the semiconductor body 104. In this context, the terms “third” and “fourth” implantation process do not denote a particular order. The implanted dopant atoms may be activated by annealing steps, which may be performed concurrently after individual implantation processes or after all implantation processes are performed.

The ESD protection device 100 comprises a first contact pad 116, a second contact pad 118 and a central interconnect structure 120. The first contact pad 116 is electrically connected to the n-type wells 108 in the first row 109. The second contact pad 118 is electrically connected to the n-type wells 108 in the second row 111. The central interconnect structure 120 is electrically connected to the p-type wells 106 in the first row 109 and the p-type wells 106 in the second row 111. The first contact pad 116, the second contact pad 118 and the central interconnect structure 120 may each be formed from an electrically conductive material, e.g., copper, aluminum, nickel, and alloys thereof. The conductive runners 122, 123 may likewise be formed from an electrically conductive material, e.g., copper, aluminum, nickel, and alloys thereof, or highly doped polysilicon.

The working principle of the ESD protection device 100 is as follows. The ESD protection device 100 is a lateral device, meaning that it is configured to conduct or block a current flowing parallel to the upper surface 102 of the semiconductor body 104. In a conduction mode of the ESD protection device 100, current flows between the first contact pad 116 and the second contact pad 118. A grouping of the n-type wells 108 in the first row 109, the p-type wells 106 in the first row 109, the p-type wells 106 in the second row 111 and the n-type wells 108 in the second row 111 collectively form a PNPN structure between the first contact pad 116 and the second contact pad 118. At one voltage polarity one of the first and second rows 109, 111 operates in SCR mode, whereas the other one of the first and second rows 109, 111 operates as a forward biased p-i-n diode. At the opposite voltage polarity, the first and second rows 109, 111 operating in SCR mode and p-i-n diode mode switch. As result of having these two devices arranged in an anti-series configuration, the ESD protection device 100 is symmetric and bidirectional as between the first contact pad 116 and the second contact pad 118. Stated another way, the ESD protection device 100 is a bidirectional device with 2 identical device structures of reversed orientation connected in series with one another.

In the depicted embodiment, the ESD protection device 100 comprises trigger regions 132 in between one of the p-type wells 106 and one of the n-type wells 108. These trigger regions 132 operate as avalanche diodes that become conductive when an avalanche breakdown condition is reached. Once the device is in the conduction state, a current flows between the n-type wells 108 and the p-type wells 106 within the semiconductor body 104. This concept can be used to form a low-ohmic current path that shunts a sudden and large current, e.g., from an ESD event, away from another device that is connected to the ESD protection device 100. In other embodiments, the triggering mechanism of the ESD protection device 100 may differ from what is shown. For example, the ESD protection device 100 may be configured to induce n-well/p-well breakdown defined by the distance between the n-type wells 108 and the p-type wells 106 and the respective doping profiles. In another embodiment, the ESD protection device 100 may be configured such that n-well/p-well breakdown between the trigger regions 132 has a lower breakdown voltage than the breakdown between the n-type wells 108 and the p-type wells 106 outside of the trigger regions 132. In another embodiment, the ESD protection device 100 comprises an external trigger device that delivers a trigger current to an n-well or p-well, which is coupled to the first and second contact pads 116, 118 and delivers a trigger current in case of the potential difference between first and second contact pads 116, 118 is exceeded. The external trigger network may be connected to the secondary electrical interconnect network 140 (to be described below) or a further interconnect network connected to at least one of the n-type wells 108 and the p-type wells 106.

The ESD protection device 100 comprises a primary electrical interconnect network 138. The primary electrical interconnect network 138 of the ESD protection device 100 refers to the electrical conductors that electrically couple groups of the p-type wells 106 and the n-type wells 108 arranged as ESD protection device fingers or segments between the first and second contact pads 116, 118. In a conduction mode of the ESD protection device 100, the operational current flows through the primary electrical interconnect network 138 between the first and second contact pads 116, 118. In the ESD protection device 100 of FIG. 1, the primary electrical interconnect network 138 consists of first conductive runners 122 extending over each of the n-type wells 108 and forming a low-ohmic connection with each of the first and second shallow doped zones 124, 126, second conductive runners 123 extending over each of the p-type wells 106 and forming a low-ohmic connection with each of the third and fourth shallow doped zones 128, 130, the central interconnect structure 120, and the interconnect busses that connect groups of the conductive runners 122, 123 with the first and second contact pads 116, 118 and the central interconnect structure 120.

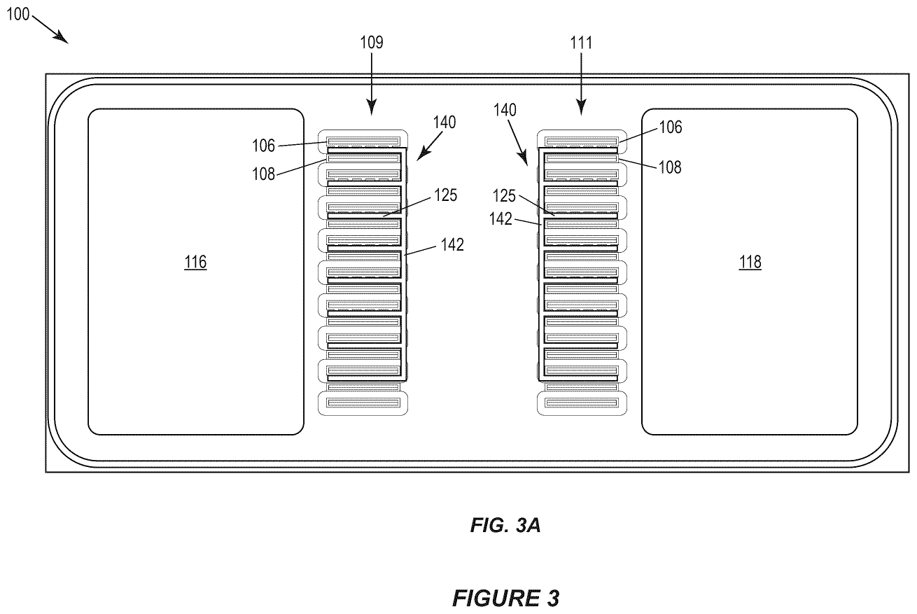

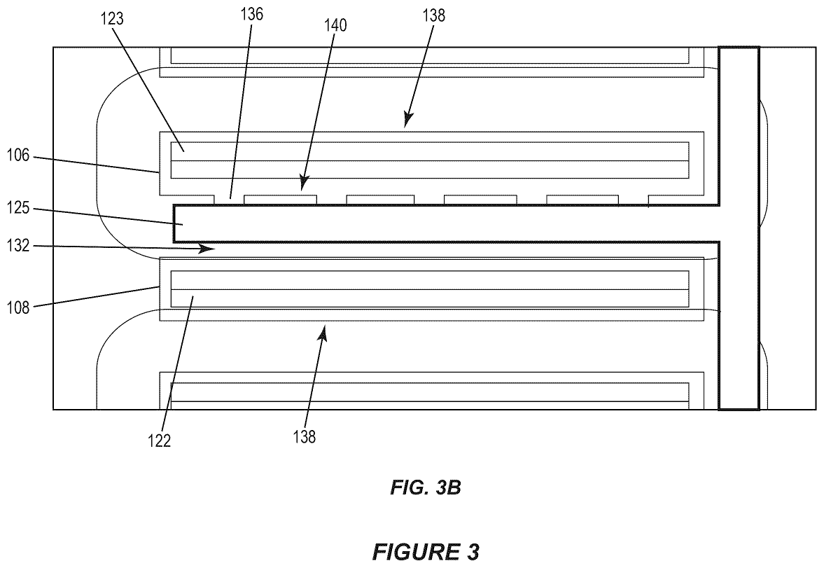

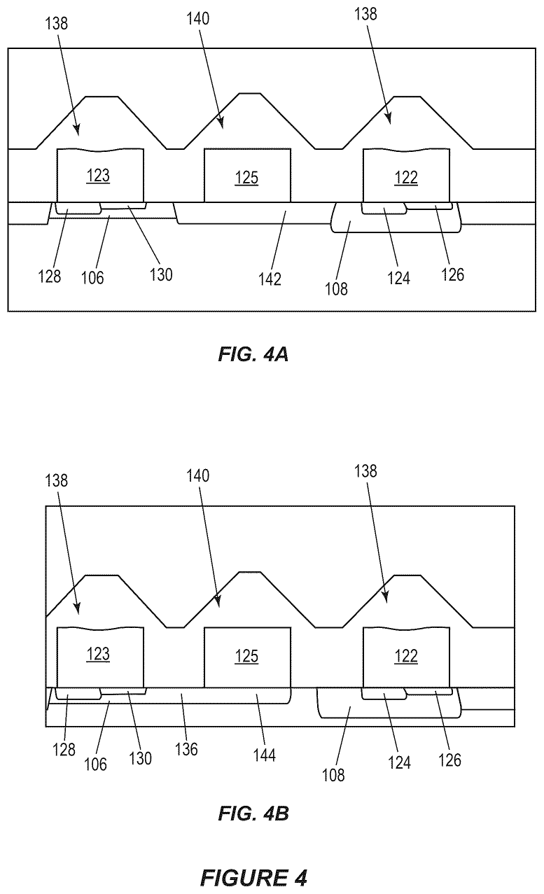

The ESD protection device 100 may optionally comprise electrical isolation regions formed in the semiconductor body 104 around the n-type wells 108 and the p-type wells 106. For simplicity sake, these electrical isolation regions have been omitted from FIG. 1, but are shown in FIGS. 3 and 4, which will be described in further detail below. These electrical isolation regions may lead to improved device performance by lowering total device capacitance. An example of an ESD protection device with electrical isolation regions is described in U.S. Pat. No. 11,776,996 to Tylaite, the content of which is described by reference herein in its entirety. In an embodiment, the ESD protection device 100 comprises the isolating regions, and the electrical isolation regions are configured such that the isolating area surrounding the p-type wells is equal to the isolating area surrounding the n-type wells. In another embodiment the ESD protection device 100 comprises the isolating regions, and the electrical isolation regions are configured such that the isolating area surrounding the p-type wells is greater than the isolating area surrounding the n-type wells, e.g., as described in the above-mentioned Tylaite reference.

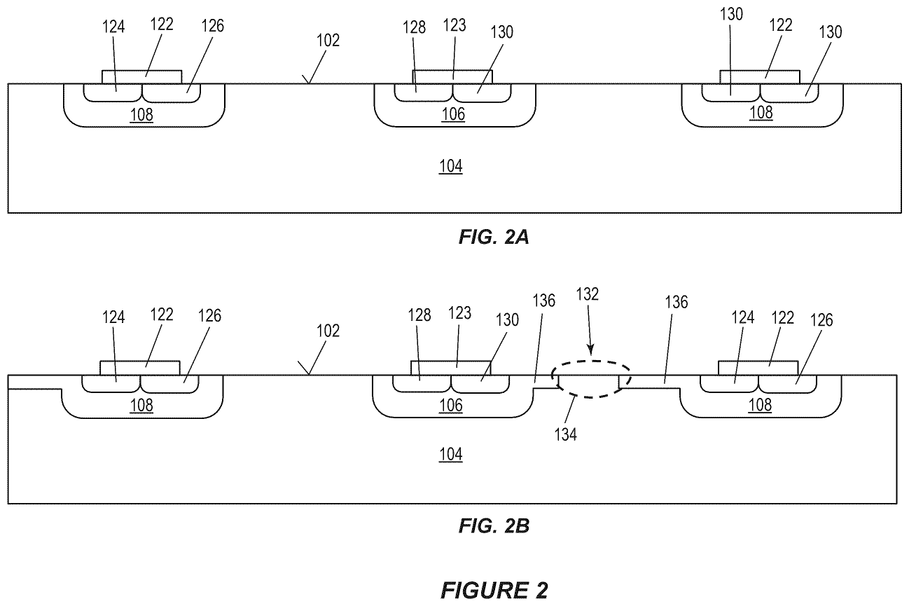

Referring to FIG. 2, the ESD protection device 100 from FIG. 1 is shown from a cross-sectional perspective. FIG. 2A shows the ESD protection device 100 along the cross-sectional plane 151 identified in FIG. 1 that extends in the first direction D1 and is between one of the trigger regions 132. FIG. 2B shows the ESD protection device 100 along the cross-sectional plane 161 identified in FIG. 1 that extends in the first direction D1 and intersects one of the trigger regions 132. As shown in FIG. 2B, the trigger regions 132 include a low-doped section 134 of the semiconductor body 104 in between one of the p-type wells 106 and one of the n-type wells 108. The breakdown voltage VBR of the avalanche diode structure that triggers conduction of the ESD protection device 100 is determined by the width of the low-doped section 134 of the semiconductor body 104 in between the p-type wells 106 and the n-type wells 108. As shown, there is an extension region 136 that merges with the p-type wells 106 and the n-type wells 108 extends towards an adjacent doped well, thereby locally reducing the effective distance between the p-type wells 106 and the n-type wells 108 to define the width of the low-doped section 134. In this way, an avalanche breakdown occurs locally where these trigger regions 132 are formed. In another embodiment, the distance between p-type wells 106 and the n-type wells 108 may be locally reduced, without providing extension regions locally at the surface. Separately or in combination, the trigger regions 132 may comprise paths of low-doped semiconductor material interposed between regions of electrical isolation material, e.g., as shown in FIG. 3B below. In general, the semiconductor material in the low-doped sections 134 can have any dopant concentration that is lower than that of the p-type wells 106 and the n-type wells 108. As shown, the low-doped sections 134 correspond to a region of intrinsic, i.e., not-intentionally doped, material from the semiconductor body 104. Alternatively, the low-doped sections 134 may be provided by lightly intentionally doped regions.

A multi-finger ESD protection device such as the ESD protection device 100 described above may be susceptible to inhomogeneous triggering behavior. As is apparent from the figures above, the ESD protection device 100 comprises trigger regions 132 associated with multiple pairings of the p-type wells 106 and the n-type wells 108 within each of the first and second rows 109, 111. Inhomogeneous triggering behavior occurs when the various conducting fingers of the ESD protection device are not triggered simultaneously. Due to factors such as statistical variation in the dynamics of triggering in combination with the removal of the trigger condition (i.e., avalanche breakdown in the trigger regions) once at least one finger has turned on, some of the trigger regions 132 do not stay long enough in avalanche breakdown state, so that some of the n-well/p-well pairs do not go from a blocking into a conducting state. This issue is particularly problematic at higher trigger voltages and/or stress pulses with longer rise times of the initial pulse flank. The issue can be self-reinforcing, as the faster triggering fingers can reduce the voltage across the remaining fingers, thereby making it less likely that an eventual triggering will occur.

Referring to FIG. 3A, an ESD protection device 100 is shown, according to an embodiment. The ESD protection device 100 of FIG. 3 comprises a secondary electrical interconnect network 140 for each of the first row 109 and the second row 111. The secondary electrical interconnect network 140 electrically connects each of the p-type wells 106 of the respective rows 109, 111 together. The secondary electrical interconnect network 140 comprises a plurality of third conductive runners 125 that extend in the second direction of the semiconductor body. Each of the third conductive runners 125 from the secondary electrical interconnect network 140 forms a low-ohmic connection with one of the p-type wells 106. The secondary electrical interconnect network 140 additionally comprises an interconnect bus 142 that is connected with each of the third conductive runners 125 and is disposed outside of the row of doped wells associated with the conductive runners 122. The interconnect bus 142 may extend in the second direction of the semiconductor body that is perpendicular to the first direction and hence intersect each of the third conductive runners 125 at orthogonal angles. The secondary electrical interconnect network 140 may be formed from electrically conductive material, e.g., a layer copper, aluminum, nickel, and alloys thereof, or highly doped polysilicon. The secondary electrical interconnect network 140 may additionally comprise regions of highly doped semiconductor material within the semiconductor body 104 that can supplant upper-level connections.

The secondary electrical interconnect network 140 forms a node that is independent from the primary electrical interconnect network 138. That is, the secondary electrical interconnect network 140 is not part of the wiring structure that accommodates operational current flowing between the first and second contact pads 116, 118 when the ESD protection device segments are in conduction mode. Instead, the third conductive runners 125 and the interconnect bus 142 form a conductive path that is not directly physically connected with the electrical conductors of the primary electrical interconnect network 138. There is an indirect connection between the primary electrical interconnect network 138 and the secondary electrical network 140, as they are each in ohmic contact with the p-type wells 106. However, this is not a direct physical connection within the context of the instant specification. As mentioned above, the primary electrical interconnect network 138 of the ESD protection device 100 refers to the electrical conductors that electrically couple the p-type wells 106 and the n-type wells 108 between the first and second contact pads 116, 118. For ease of illustration, only the conductive runners 122, 123 from the primary electrical interconnect network 138 of the ESD protection device 100 of FIG. 3 are shown.

The secondary electrical interconnect network 140 equalizes the local potential in each of the p-type wells 106 connected thereto. As a result, once one of the fingers has triggered, and the others would not trigger due to ceasing of the triggering condition, the resulting state of potential distribution in the turned-on finger is transferred to the not-yet triggered fingers. This will apply the trigger condition to the other not-yet triggered fingers and force them to go into conducting state too.

According to another embodiment, the ESD protection device 100 is configured such that the secondary electrical interconnect network 140 electrically connects each of the n-type wells 108 of the respective row together. In this embodiment, the ESD protection device 100 is identical to the device of FIG. 3, except that the secondary electrical interconnect network 140 is arranged such that the third conductive runners 125 extend over and form an ohmic connection with each of the n-type wells 108. This achieves the same potential equalization effect as described above, and consequently mitigates inhomogeneous triggering behavior, which in turn ensures that each finger of the ESD protection device becomes conductive and the full operational current is distributed in parallel.

Referring to FIG. 3B, a close-up view of the ESD protection device is shown in the vicinity of the trigger regions 132. As shown, the third conductive runners 125 from the secondary electrical interconnect network 140 are arranged between one of the first conductive runners 122 from the primary electrical interconnect network 138 extending over one of the n-type wells 108 and one of the second conductive runners 123 from the primary electrical interconnect network 138 extending over one of the p-type wells 106. As shown, the ESD protection device 100 comprises extension regions 136 of the p-type wells 106 that extend towards the n-type wells 108 and are used to form the trigger regions 132. In one embodiment these extension regions 136 of the p-type wells 106 are additionally used as well-taps to form a direct connection with the secondary electrical interconnect network 140. The conductive runners 125 from the secondary electrical interconnect network 140 extend across the device so as to overlap with the extension regions 136 and facilitate a low-ohmic connection thereto. In an alternate configuration wherein a secondary electrical interconnect network 140 electrically connects the n-type wells 108 together, a similar arrangement may be used, wherein the conductive runners 125 from the secondary electrical interconnect network 140 extend across extension regions 136 of the n-type wells 108.

Multi-level interconnect structures may be used to accommodate both the secondary electrical interconnect network 140 and the primary electrical interconnect network 138. Multi-level interconnect structures refer to wiring structures that comprise multiple levels of metallization and via structures extending between these levels of metallization. For example, in an embodiment, the secondary electrical interconnect network 140 is a continuous structure formed in a lower-level metallization of the semiconductor device, and the primary electrical interconnect network 138 is at least partially formed in an upper-level metallization of the semiconductor device that is vertically separated from the lower-level metallization. In this embodiment, the first conductive runners 122 forming a low-ohmic connection with each of the first and second shallow doped zones 124, 126 and the second conductive runners 123 forming a low-ohmic connection with each of the third and fourth shallow doped zones 128, 130 may be contacted by via structures that are in connection with upper-level metallization tracks that are overlaid over the secondary electrical interconnect network 140.

Referring to FIG. 4, cross-sectional views of the ESD protection device from FIG. 3 are shown. As shown in FIG. 4A, the third conductive runners 125 from the secondary electrical interconnect network 140 do not form any connection with the semiconductor body where no extension region 136 exists. As shown in FIG. 4B, the third conductive runners 125 from the secondary electrical interconnect network 140 overlap with the extension regions 136 of the p-type wells 106 and from a low-ohmic contact to the p-type wells 106 in these locations. The ESD protection device may comprise a thin barrier layer on the upper surface 102 of the semiconductor body 104, which may be patterned to comprise openings to facilitate a direct connection.

As shown in FIG. 4B, the ESD protection device 100 comprises fifth shallow doped zones 144 disposed within the extension regions 136 of the p-type wells 106. These fifth shallow doped zones 144 are p-type regions with a higher dopant concentration than the underlying concentration of the p-type wells 106. The fifth shallow doped zones 144 facilitate a low-ohmic connection to the third conductive runners 125 from the secondary electrical interconnect network 140. The fifth shallow doped zones 144 may be formed by a similar technique and/or have a similar dopant concentration as the first and third shallow doped zones 124, 128 described above. In an alternate configuration wherein a secondary electrical interconnect network 140 electrically connects the n-type wells 108 together, a similar arrangement may be used, wherein the fifth shallow doped zones 144 correspond to n-type regions that are formed within extension regions 136 of the n-type wells 108. In that case, the fifth shallow doped zones 144 may be formed by a similar technique and/or have a similar dopant concentration as the second and fourth shallow doped zones 126, 130 described above.

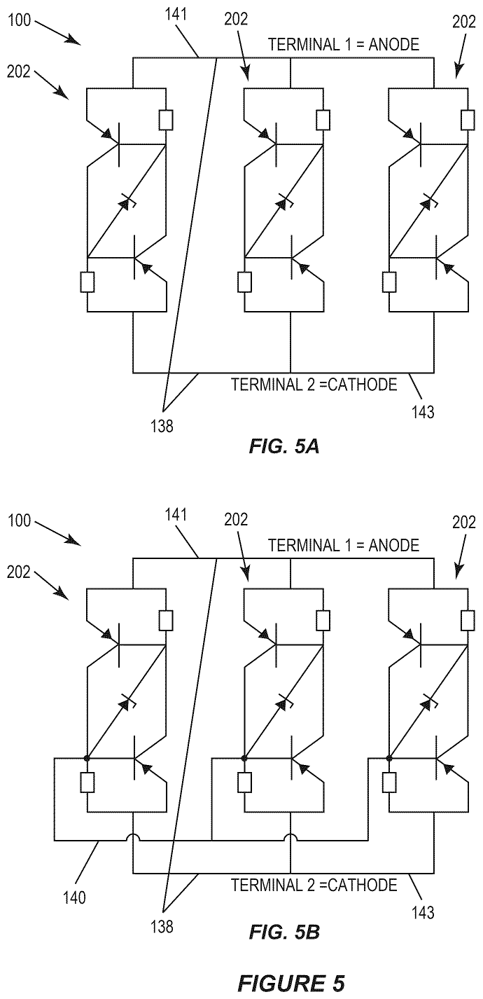

Referring to FIG. 5, ESD protection devices 100 are schematically depicted, according to embodiment. Each ESD protection device 100 comprises a plurality of silicon-controlled rectifier devices 202 connected in parallel between an anode terminal 141 and a cathode terminal via a primary electrical interconnect network 138. The silicon-controlled rectifier devices 202 correspond to a grouping of the p-type wells 106 and the n-type wells 108 and associated first, second, third and fourth shallow doped zones 124, 126, 128, 130 connected between the first and second contact pads 116, 118 by the primary electrical interconnect network 138. The ESD protection devices 100 shown in FIG. 5 may schematically represent one of the two bidirectional devices from the ESD protection device 100 described with reference to FIGS. 1-2, e.g., wherein the central interconnect structure 120 corresponds to the anode terminal 141 or the cathode terminal 143.

In the embodiment of FIG. 5A, the device is devoid of the secondary electrical interconnect network 140 as described above. This multi-finger device is susceptible to inhomogeneous triggering behavior as the branches (fingers) of the device are constructed with separate n-doped wells and p-doped wells which allows that the potential distribution in the n-doped wells corresponding to a switched-on state to be established in each of the n-doped wells independent of the other n-doped wells in the multi-finger device, and which allows that the potential distribution in the p-doped wells corresponding to a switched-on state to be established in each of the p-doped wells independent of the other p-doped wells in the multi-finger device. In other words, in this embodiment the gate terminals or the regions of the n-doped or p-doped wells in which a gate terminal to establish a controlled switching-on of the SCR could have been disposed, are all floating independently from each other.

In the embodiment of FIG. 5B, the device comprises the secondary electrical interconnect network 140 as described above. The secondary electrical interconnect network 140 forms a separate electrical connection between the p-doped wells which form the anode regions of each trigger device, i.e., the p-type wells 106 which form part of the avalanche diodes. Accordingly, the device is less susceptible to inhomogeneous triggering behavior as the local potential in the p-doped well of a switched-on device finger is transferred to the corresponding location of the p-doped well of the other fingers in the device. In case one or more fingers are not yet triggered the transfer of the local potential of the triggered fingers in the device will impose the triggering condition on the fingers that have not yet triggered. In other words, in this embodiment the gate terminals or the regions of the p-doped wells, in which a gate terminal to establish a controlled switching-on of the SCR could have been disposed, are all electrically coupled to each other, so that the local potential in the gate region of the one or more switched-on sections/fingers/branches is transferred to the one or more not switched-on sections/fingers/branches.

In another embodiment, the secondary electrical interconnect network 140 may form a separate electrical connection between the doped wells which form the cathode regions of each trigger device, i.e., the n-type wells 108 which form part of the avalanche diodes. In that case a similar mitigation of inhomogeneous triggering behavior may be realized.

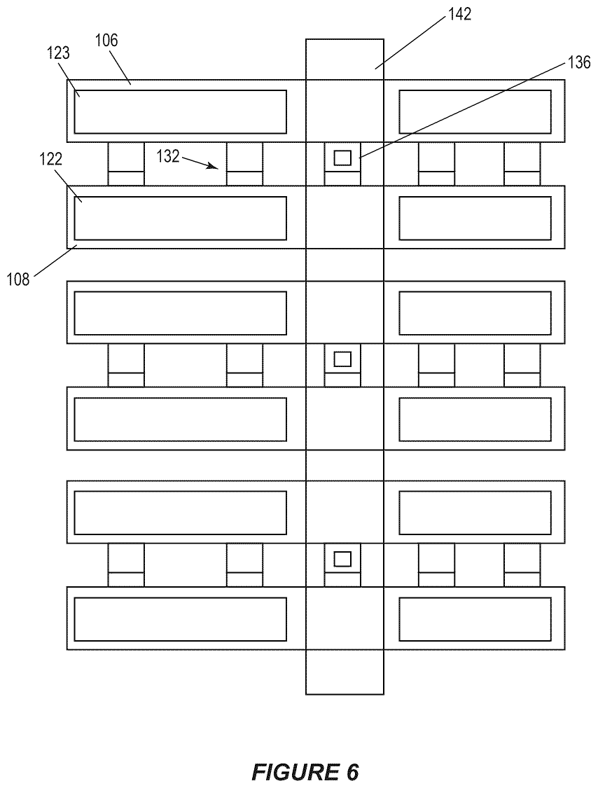

Referring to FIG. 6, an alternate layout of the ESD protection device 100 is shown, according to an embodiment. In comparison to the embodiment of FIG. 3, the connection of the secondary electrical interconnect network 140 with the p-type wells 106 is modified. In this case, the third conductive runners 123 are omitted from the secondary electrical interconnect network 140. Instead, the secondary electrical interconnect network 140 comprises an interconnect bus 142 that is disposed within a laterally central location of one of the rows 109, 11 of doped wells. This interconnect bus 142 extends directly over the extension regions 136 and forms a direct connection to the p-type wells 106.

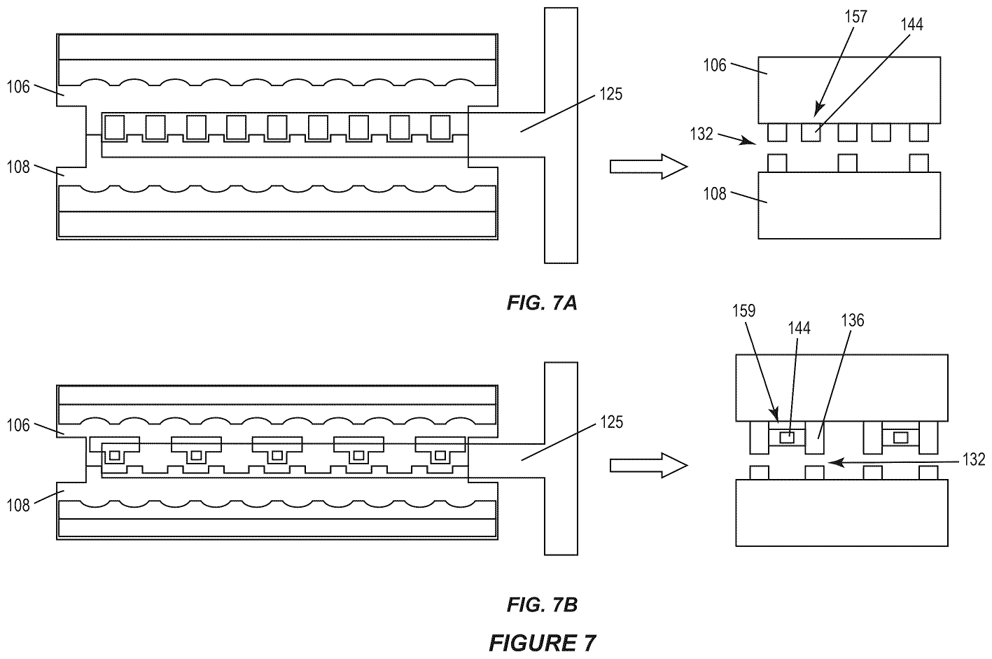

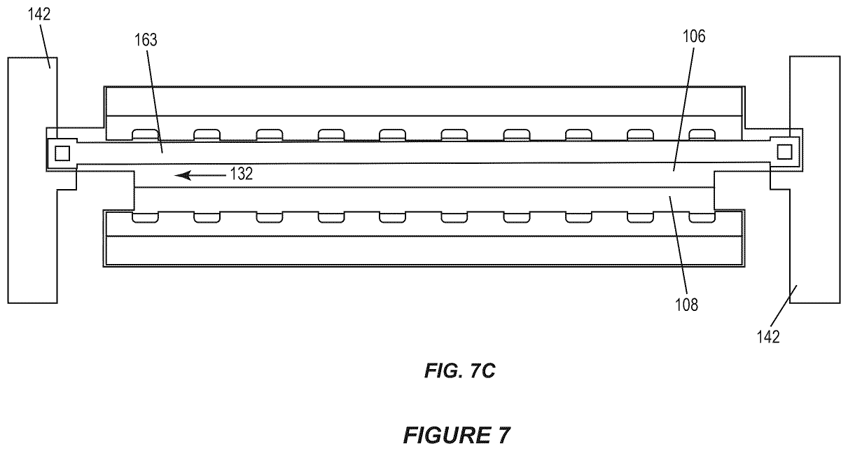

Referring to FIG. 7, alternate layouts of the ESD protection device 100 are shown, according to embodiments. In the embodiment of FIG. 7A, the ESD protection device 100 comprises dedicated well taps 157 that are outside of the trigger regions 132. These dedicated well taps 157 are directly contacted by the secondary electrical interconnect network 140. In the embodiment of FIG. 7B, the ESD protection device 100 comprises bridge spans 159 extending between the extension regions 136. These bridge spans 159 form separate locations for connection the secondary electrical interconnect network 140. In the embodiment of FIG. 7C, the ESD protection device 100 comprises a continuous shallow doped zone 163 that laterally extends across each of the trigger regions 132 and forms a low-ohmic contact with the p-type wells 106. The continuous shallow doped zone 163 replaces third conductive runners 123 from the previously described embodiments. The secondary electrical interconnect network 140 contacts the continuous shallow doped zone 163 with interconnect busses 142 on either end of the p-type wells 106. In each of the embodiments, the secondary electrical interconnect network 140 forms direct connections with each of the p-type wells 106 so as to equalize potential as between fingers. A similar concept may be used to connect with each of the n-type wells 108.

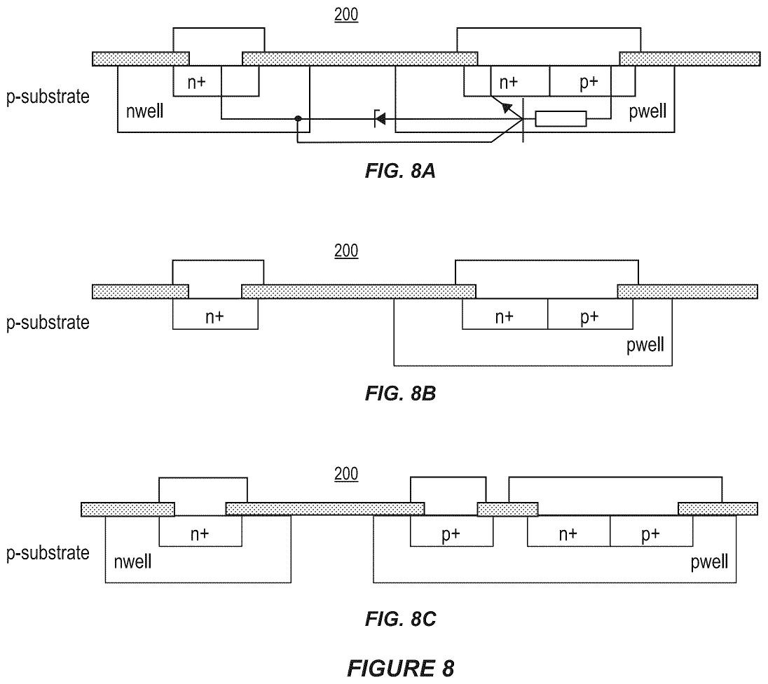

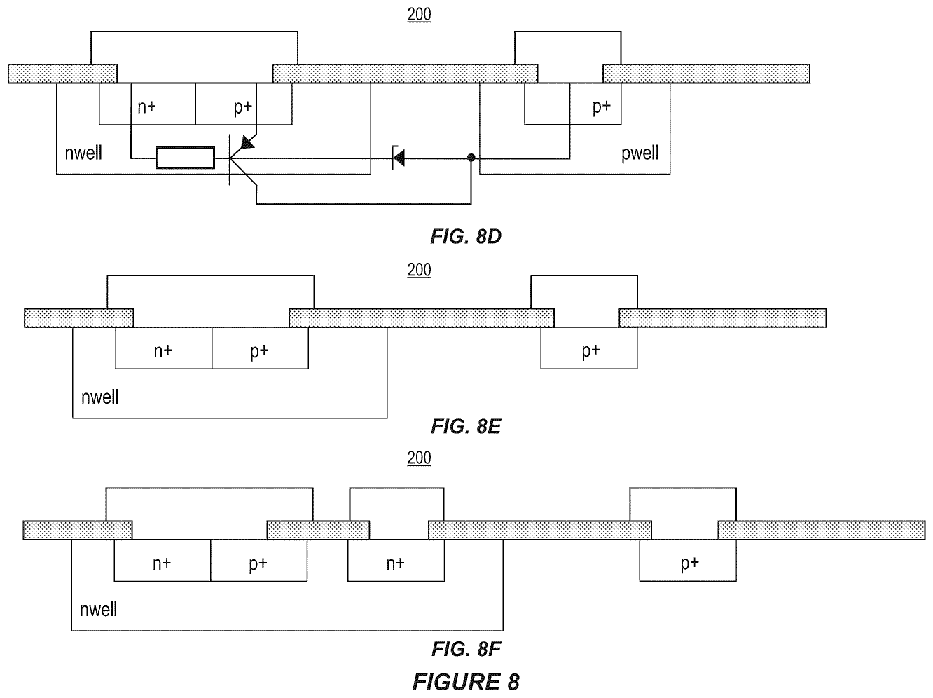

Referring to FIG. 8, various embodiments of ESD protection device 200 are shown, according to embodiments. In each of these embodiments, a secondary electrical interconnect network 140 as described above may be used to equalize the potential of like-doped wells and synchronize triggering manner in the same manner described above. To the extent consistent with the various device concepts, any of the previously described layout configurations of the secondary electrical interconnect network 140 and associated well designs for connecting the secondary electrical interconnect network 140 with each of the doped wells may be used in combination with the embodiments shown in FIG. 8. Each of the embodiments of FIG. 8 differ from the ESD protection device 100 described with reference to FIGS. 1-2 in that these ESD protection devices 200 are not configured as a bidirectional silicon-controlled rectifier device. FIG. 8A shows a first example of an ESD protection device 200 that is configured as an NPN bipolar device with shorted, shallow, n+ doped emitter and p+ doped base contact regions. The figure additionally shows a schematic representation of the equivalent circuit diagram, including a distributed resistor inside the p-well base region and a diode representing the avalanche breakdown between the n-doped collector and p-doped base region. FIG. 8B illustrates an alternative embodiment without the n-well in the collector region. FIG. 8C illustrates a device similar to that of FIG. 8A that additionally includes a p+ base tap to sense the local potential drop and to distribute the local potential of a switched on finger a blocking finger by a secondary interconnect network, which may be configured as the secondary electrical interconnect network 140 described above. FIGS. 8D, 8E and 8F illustrate the PNP equivalents of FIGS. 8A, 8B and 8C.

In addition to the described ESD protection device 100 described above, the concepts described herein, and in particular the provision of a secondary electrical network that mitigates inhomogeneous triggering, may be incorporated into a variety of different ESD protection devices. These ESD protection devices 100 include unidirectional devices and p-i-n diodes and bipolar junction transistor devices and silicon-controlled rectifier devices with one floating gate, for example. In one particular example, the second and fourth shallow doped zones 126, 130 may be omitted from the device. In one other particular example the first and or the fourth shallow doped zone 124, 130 may be omitted from the device.

Although the present disclosure is not so limited, the following numbered examples demonstrate one or more aspects of the disclosure.
Example 1. A semiconductor device, comprising: a first row of doped wells formed in an upper surface of a semiconductor body, the first row comprising first conductivity type wells arranged alternatingly with second conductivity type wells in a first direction of the semiconductor body; first and second contact pads disposed over the upper surface of the semiconductor body, a primary electrical interconnect network that electrically couples the first conductivity type wells and the second conductivity type wells from the first row between the first and second contact pads, and a secondary electrical interconnect network that forms a node that is independent from the primary electrical interconnect network and electrically connects each of the first conductivity type wells in the first row together.
Example 2. The semiconductor device of claim 1, wherein the secondary electrical interconnect network comprises a plurality of conductive runners, wherein each of the first conductivity type wells form a low-ohmic connection with one of the conductive runners.
Example 3. The semiconductor device of example 2, wherein the secondary electrical interconnect network further comprises an interconnect bus connects with each of the conductive runners from the secondary electrical interconnect network.
Example 4. The semiconductor device of example 3, wherein the interconnect bus extends in the first direction of the semiconductor body.
Example 5. The semiconductor device of example 3, wherein the secondary electrical interconnect network is a continuous structure formed in a lower-level metallization of the semiconductor device, and wherein the primary electrical interconnect network is at least partially formed in an upper-level metallization of the semiconductor device that is vertically separated from the lower-level metallization.
Example 6. The semiconductor device of example 2, wherein the conductive runners from the secondary electrical interconnect network are arranged between a first one of the conductive runners from the primary electrical interconnect network that extends over and is electrically coupled with one of the first conductivity type wells and a second one of the conductive runners from the primary electrical interconnect network that extends over and is electrically coupled with one of the second conductivity type wells.
Example 7. The semiconductor device of example 2, wherein each of the first conductivity type wells in the first row comprise a plurality of extension regions that extend towards one of the second conductivity type wells in the first row, and wherein the conductive runners extend across and overlap with the extension regions and form a plurality of the low-ohmic connections via the extension regions.
Example 8. The semiconductor device of example 7, wherein each of the extension regions comprise a first conductivity type shallow doped zone that interface with one of the conductive runners, wherein the first conductivity type shallow doped zones are more highly doped than subjacent portions of the first conductivity type wells.
Example 9. The semiconductor device of example 1, wherein the first conductivity type is p-type and the second conductivity type is n-type.
Example 10. The semiconductor device of example 1, wherein the first conductivity type is n-type and the second conductivity type is p-type.
Example 11. The semiconductor device of example 1, further comprising first and second shallow doped zones arranged within each of the first conductivity type wells, and third and fourth shallow doped zones arranged within each of the second conductivity type wells, wherein the first and third shallow doped zones are p-type regions, and wherein the second and fourth shallow doped zones are n-type regions.
Example 12. The semiconductor device of example 1, further comprising: a second row of doped wells formed in the upper surface of the semiconductor body, the second row comprising first conductivity type wells arranged alternatingly with second conductivity type wells in the first direction of the semiconductor body; trigger regions configured to induce current flow between one of the first conductivity type wells and one of the second conductivity type wells from the second row, wherein the primary electrical interconnect network electrically couples rectifier devices formed by groups of the first conductivity type wells and the second conductivity type wells from the second row between the first and second contact pads, and wherein the semiconductor device further comprises an additional secondary electrical interconnect network that forms a separate node that is independent from the primary electrical interconnect network and electrically connects each of the first conductivity type wells in the second row together.
Example 12. The semiconductor device of example 1, further comprising trigger regions configured to induce current flow between one of the first conductivity type wells and one of the second conductivity type wells from the first row.
Example 13. The semiconductor device of example 1, further comprising a second row of doped wells formed in the upper surface of the semiconductor body, the second row comprising first conductivity type wells arranged alternatingly with second conductivity type wells in the first direction of the semiconductor body; wherein the primary electrical interconnect network electrically couples semiconductor device segments formed by groups of the first conductivity type wells and the second conductivity type wells from the second row between the first and second contact pads, and wherein the semiconductor device further comprises an additional secondary electrical interconnect network that forms a separate node that is independent from the primary electrical interconnect network and independent of the secondary network of the first row of doped wells and electrically connects each of the first conductivity type wells in the second row together.
Example 14. A semiconductor device, comprising: a plurality of silicon-controlled rectifier devices connected in parallel and electrically coupled to an anode terminal and a cathode terminal via a primary electrical interconnect network, each of the silicon-controlled rectifier devices comprising a trigger device that is configured to create a trigger current that places the device into conduction mode; and a secondary electrical interconnect network that forms a node that is independent from the primary electrical interconnect network and electrically connects a doped region that is part of or connected with terminals from each of the trigger devices together.
Example 15. The semiconductor device of example 14, wherein the at least one trigger device is configured as an avalanche diode, and wherein the secondary electrical interconnect network electrically connects each of the anodes of the avalanche diodes together.
Example 16. The semiconductor device of example 14, wherein the at least one trigger device is configured as an avalanche diode, and wherein the secondary electrical interconnect network electrically connects each of the cathodes of the avalanche diodes together.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc. and are also not intended to be limiting. Like terms refer to like elements throughout the description.

As used herein, the terms “having,” “containing,” “including,” “comprising” and the like are open-ended terms that indicate the presence of stated elements or features, but do not preclude additional elements or features. The articles “a,” “an” and “the” are intended to include the plural as well as the singular, unless the context clearly indicates otherwise.

With the above range of variations and applications in mind, it should be understood that the present invention is not limited by the foregoing description, nor is it limited by the accompanying drawings.

1. A semiconductor device, comprising:
a first row of doped wells formed in an upper surface of a semiconductor body, the first row comprising first conductivity type wells arranged alternatingly with second conductivity type wells in a first direction of the semiconductor body;
first and second contact pads disposed over the upper surface of the semiconductor body;
a primary electrical interconnect network that electrically couples the first conductivity type wells and the second conductivity type wells from the first row between the first and second contact pads; and
a secondary electrical interconnect network that forms a node that is independent from the primary electrical interconnect network and electrically connects each of the first conductivity type wells in the first row together.

2. The semiconductor device of claim 1, wherein the secondary electrical interconnect network comprises a plurality of conductive runners, wherein each of the first conductivity type wells form a low-ohmic connection with one of the conductive runners.

3. The semiconductor device of claim 2, wherein the secondary electrical interconnect network further comprises an interconnect bus that connects with each of the conductive runners from the secondary electrical interconnect network.

4. The semiconductor device of claim 3, wherein the interconnect bus extends in the first direction of the semiconductor body.

5. The semiconductor device of claim 3, wherein the secondary electrical interconnect network is a continuous structure formed in a lower-level metallization of the semiconductor device, and wherein the primary electrical interconnect network is at least partially formed in an upper-level metallization of the semiconductor device that is vertically separated from the lower-level metallization.

6. The semiconductor device of claim 2, wherein the conductive runners from the secondary electrical interconnect network are arranged between a first one of the conductive runners from the primary electrical interconnect network that extends over and is electrically coupled with one of the first conductivity type wells and a second one of the conductive runners from the primary electrical interconnect network that extends over and is electrically coupled with one of the second conductivity type wells.

7. The semiconductor device of claim 2, wherein each of the first conductivity type wells in the first row comprises a plurality of extension regions that extend towards one of the second conductivity type wells in the first row, and wherein the conductive runners extend across and overlap with the extension regions and form a plurality of the low-ohmic connections via the extension regions.

8. The semiconductor device of claim 7, wherein each of the extension regions comprises a first conductivity type shallow doped zone that interfaces with one of the conductive runners, wherein the first conductivity type shallow doped zones are more highly doped than subjacent portions of the first conductivity type wells.

9. The semiconductor device of claim 1, wherein the first conductivity type is p-type and the second conductivity type is n-type.

10. The semiconductor device of claim 1, wherein the first conductivity type is n-type and the second conductivity type is p-type.

11. The semiconductor device of claim 1, further comprising first and second shallow doped zones arranged within each of the first conductivity type wells, and third and fourth shallow doped zones arranged within each of the second conductivity type wells, wherein the first and third shallow doped zones are p-type regions, and wherein the second and fourth shallow doped zones are n-type regions.

12. The semiconductor device of claim 1, further comprising trigger regions configured to induce current flow between one of the first conductivity type wells and one of the second conductivity type wells from the first row.

13. The semiconductor device of claim 1, further comprising:
a second row of doped wells formed in the upper surface of the semiconductor body, the second row comprising first conductivity type wells arranged alternatingly with second conductivity type wells in the first direction of the semiconductor body; and
wherein the primary electrical interconnect network electrically couples semiconductor device segments formed by groups of the first conductivity type wells and the second conductivity type wells from the second row between the first and second contact pads, and
wherein the semiconductor device further comprises an additional secondary electrical interconnect network that forms a separate node that is independent from the primary electrical interconnect network and independent of the secondary network of the first row of doped wells and electrically connects each of the first conductivity type wells in the second row together.

14. A semiconductor device, comprising:
a plurality of silicon-controlled rectifier devices connected in parallel and electrically coupled to an anode terminal and a cathode terminal via a primary electrical interconnect network, each of the silicon-controlled rectifier devices comprising at least one trigger device that is configured to create a trigger current that places the device into conduction mode; and
a secondary electrical interconnect network that forms a node that is independent from the primary electrical interconnect network and electrically connects a doped region that is part of or coupled with terminals from each of the trigger devices together.

15. The semiconductor device of claim 14, wherein the at least one trigger device is configured as an avalanche diode, and wherein the secondary electrical interconnect network electrically connects each of the anodes of the avalanche diodes together.

16. The semiconductor device of claim 14, wherein the at least one trigger device is configured as an avalanche diode, and wherein the secondary electrical interconnect network electrically connects each of the cathodes of the avalanche diodes together.
